(19) United States
(12) Patent Application Publication
(10) Pub. No.: US 2026/0214899 A1
(43) Pub. Date: Jul. 23, 2026

(54) SEMICONDUCTOR DEVICES

(71) Applicant: SAMSUNG ELECTRONICS CO., LTD., Suwon-si (KR)

(72) Inventors: Hyunmook CHOI, Suwon-si (KR); Junghoon PARK, Suwon-si (KR)

(73) Assignee: SAMSUNG ELECTRONICS CO., LTD., Suwon-si (KR)

(21) Appl. No.: 19/454,689

(22) Filed: Jan. 21, 2026

(30) Foreign Application Priority Data
Jan. 22, 2025 (KR) 10-2025-0009276

(51) Int. Cl. H10B 43/27; H10B 43/10; H10B 43/35; H10B 43/40; H10B 43/50; H10B 80/00; H10D 30/01; H10D 30/69; H10D 80/30; H10W 20/41; H10W 80/00; H10W 90/00

(52) U.S. Cl. CPC H10B 43/27; H10B 43/10; H10B 43/35; H10B 43/40; H10B 43/50; H10B 80/00; H10D 30/693; H10D 30/696; H10D 80/30; H10W 20/435; H10W 80/312; H10W 90/792; H10D 30/0413

(57) ABSTRACT

A semiconductor device includes first gate electrodes spaced apart from each other in a vertical direction perpendicular to an upper surface of a substrate, a second gate electrode extending in the vertical direction through the first gate electrodes, and a memory channel structure on a sidewall of the second gate electrode. The memory channel structure includes a second ion reservoir pattern disposed on the sidewall of the second gate electrode and extending in the vertical direction, a second electrolyte pattern disposed on a sidewall of the second ion reservoir pattern and extending in the vertical direction, a channel disposed on a sidewall of the second electrolyte pattern and extending in the vertical direction, and first ion reservoir patterns disposed between the channel and sidewalls of the first gate electrodes, respectively, and spaced apart from each other in the vertical direction.

### CROSS-REFERENCE TO RELATED APPLICATIONS

This application claims priority under 35 USC § 119 to Korean Patent Application No 10-2025-0009276, filed on Jan. 22, 2025 in the Korean Intellectual Property Office (KIPO), the contents of which are herein incorporated by reference in their entirety.

### TECHNICAL FIELD

The inventive concepts relate to a semiconductor device and a method of manufacturing the same. More particularly, the inventive concepts relate to a vertical memory device and a method of manufacturing the same.

### DISCUSSION OF RELATED ART

A vertical memory device includes a plurality of memory cells stacked in a vertical direction on a substrate. As the integration degree of the vertical memory device increases, interference between neighboring ones of the memory cells in the vertical direction increases, and thus a method of reducing the interference is needed.

### SUMMARY

Example embodiments provide a semiconductor device having improved characteristics.

Example embodiments provide a method of manufacturing a semiconductor device having improved characteristics.

According to an aspect of the inventive concept, there is provided a semiconductor device. The semiconductor device may include first gate electrodes spaced apart from each other in a vertical direction perpendicular to an upper surface of a substrate, a second gate electrode extending in the vertical direction through the first gate electrodes, and a memory channel structure on a sidewall of the second gate electrode. The memory channel structure may include a second ion reservoir pattern disposed on the sidewall of the second gate electrode and extending in the vertical direction, a second electrolyte pattern disposed on a sidewall of the second ion reservoir pattern and extending in the vertical direction, a channel disposed on a sidewall of the second electrolyte pattern and extending in the vertical direction, and first ion reservoir patterns disposed between the channel and sidewalls of the first gate electrodes, respectively, and spaced apart from each other in the vertical direction.

According to an aspect of the inventive concept, there is provided a semiconductor device. The semiconductor device may include first gate electrodes spaced apart from each other in a vertical direction perpendicular to an upper surface of a substrate, a second gate electrode extending in the vertical direction through the first gate electrodes, and a memory channel structure on a sidewall of the second gate electrode. The memory channel structure may include a second ion reservoir pattern disposed on the sidewall of the second gate electrode and extending in the vertical direction, a second barrier pattern disposed on a sidewall of the second ion reservoir pattern and extending in the vertical direction, a channel disposed on a sidewall of the second barrier pattern and extending in the vertical direction, and first ion reservoir patterns disposed between the channel and sidewalls of the first gate electrodes, respectively, and spaced apart from each other in the vertical direction.

According to an aspect of the inventive concept, there is provided a semiconductor device. The semiconductor device may include a peripheral circuit pattern on a substrate, a bit line on the peripheral circuit pattern, first gate electrodes on the bit line and being spaced apart from each other in a vertical direction perpendicular to an upper surface of the substrate, a second gate electrode extending in the vertical direction through the first gate electrodes, a memory channel structure disposed on a sidewall of the second gate electrode and electrically connected to the bit line, and a common source plate (CSP) disposed on and electrically connected to the memory channel structure. The memory channel structure may include a second ion reservoir pattern disposed on the sidewall of the second gate electrode and extending in the vertical direction, a second electrolyte pattern disposed on a sidewall of the second ion reservoir pattern and extending in the vertical direction, a channel disposed on a sidewall of the second electrolyte pattern and extending in the vertical direction, and first ion reservoir patterns disposed between the channel and sidewalls of the first gate electrodes, respectively, and spaced apart from each other in the vertical direction.

According to an aspect of the inventive concept, there is provided a method of manufacturing a semiconductor device. In the method, insulation layers and sacrificial layers may be alternately and repeatedly stacked on a substrate in a vertical direction perpendicular to an upper surface of the substrate to form a mold layer. A hole may be formed through the mold layer to expose the upper surface of the substrate. Lateral portions of the sacrificial layers exposed by the hole may be partially removed to form recesses, respectively. First ion reservoir patterns may be formed in the recesses, respectively. A channel, a first electrolyte pattern and a second ion reservoir pattern may be formed on a sidewall of the hole. A second gate electrode may be formed in a remaining portion of the hole. The sacrificial layers may be replaced with first gate electrodes, respectively.

In example embodiments, after forming first ion reservoir patterns in the recesses, second electrolyte patterns may be further formed in the recesses, respectively.

In example embodiments, after forming second electrolyte patterns in the recesses, first barrier patterns may be further formed in the recesses, respectively.

In example embodiments, prior to forming the channel on the sidewall of the hole, a second barrier pattern may be further formed on the sidewall of the hole.

In example embodiments, after forming the first ion reservoir patterns, first barrier patterns may be further formed in the recesses, respectively.

In example embodiments, prior to forming the first barrier patterns, second electrolyte patterns may be further formed in the recesses, respectively. The first barrier patterns may be formed to contact the second electrolyte patterns, respectively.

In example embodiments, a second barrier pattern may be further formed between the first electrolyte pattern and the second ion reservoir pattern.

In example embodiments, the second gate electrode may have a shape of a pillar extending in the vertical direction, and the second ion reservoir pattern may cover a sidewall of the second gate electrode.

In example embodiments, each of the first ion reservoir patterns may have a shape of a circular ring.

In example embodiments, a first wiring may be further formed to contact an upper surface of the second gate electrode. A second wiring may be further formed to be electrically connected to the channel.

In the semiconductor device in accordance with example embodiments, interference or disturbance between neighboring memory cells may be reduced. Additionally, an amount of ions provided to the channels included in the memory cells far from the bit line may be sufficient.

### BRIEF DESCRIPTION OF THE DRAWINGS

FIG. 1 is a vertical cross-sectional view illustrating a semiconductor device in accordance with example embodiments.

FIG. 2 is an enlarged cross-sectional view of region X in FIG. 1.

FIG. 3 is a horizontal cross-sectional view taken along line A-A′ in FIG. 2.

FIG. 4 is a horizontal cross-sectional view taken along line B-B′ in FIG. 2.

FIGS. 5 to 12 are cross-sectional views illustrating a method of manufacturing a semiconductor device in accordance with example embodiments.

FIGS. 13 to 18 are enlarged cross-sectional views of region X in FIG. 1 to illustrate first memory channel structures included in semiconductor devices, respectively, in accordance with example embodiments.

FIGS. 19 and 20 are enlarged cross-sectional views of region X in FIG. 1 to illustrate second memory channel structures included in semiconductor devices, respectively, in accordance with example embodiments.

FIG. 21 is an enlarged cross-sectional view of region X in FIG. 1 to illustrate a third memory channel structure included in a semiconductor device in accordance with example embodiments.

FIG. 22 is a cross-sectional view illustrating a semiconductor device in accordance with example embodiments.

### DETAILED DESCRIPTION

Hereinafter, a semiconductor device and a method for manufacturing the same in accordance with example embodiments will be described in detail with reference to the accompanying drawings. It will be understood that, although the terms “first,” “second,” and/or “third” may be used herein to describe various elements, these elements should not be limited by these terms. These terms are only used to distinguish one element from another element.

In the specification (and not necessarily in the claims), a vertical direction substantially perpendicular to an upper surface of a first substrate or a second substrate may be referred to as a first direction D1, and two directions crossing each other among horizontal directions substantially parallel to the upper surface of the first substrate or the second substrate may be referred to as second and third directions D2 and D3, respectively. In example embodiments, the second and third directions may be substantially perpendicular to each other.

Each of the first to third directions D1, D2 and D3 may represent not only a direction shown in the drawing, but also a reverse direction to the direction.

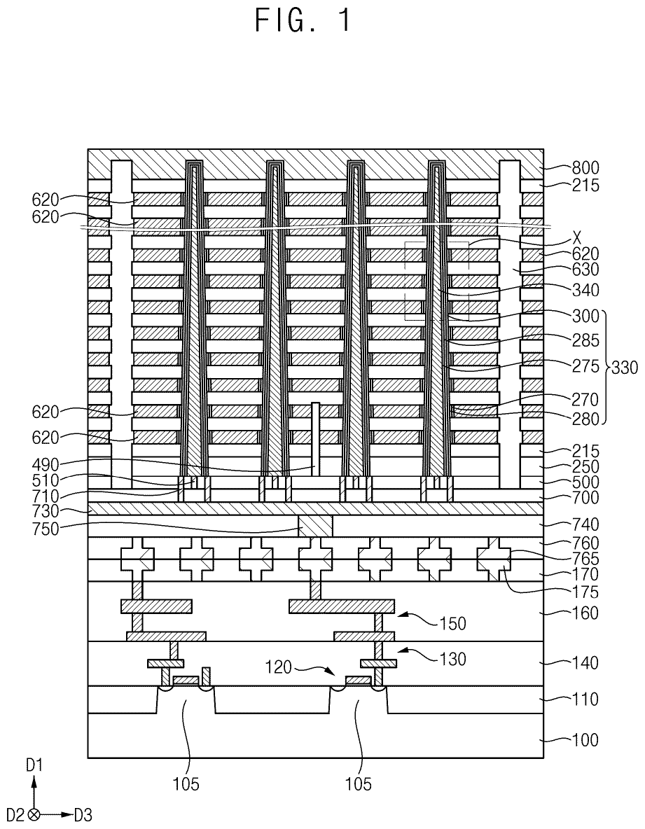

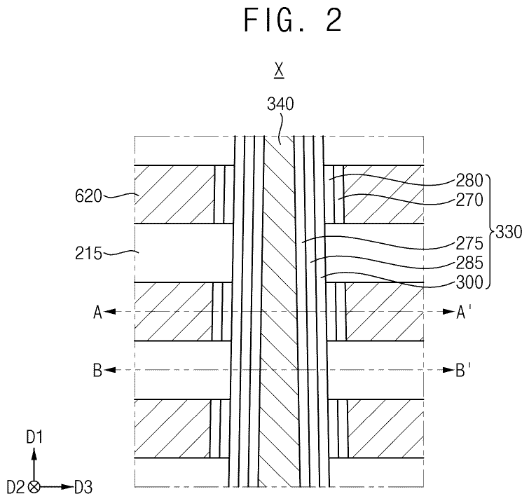

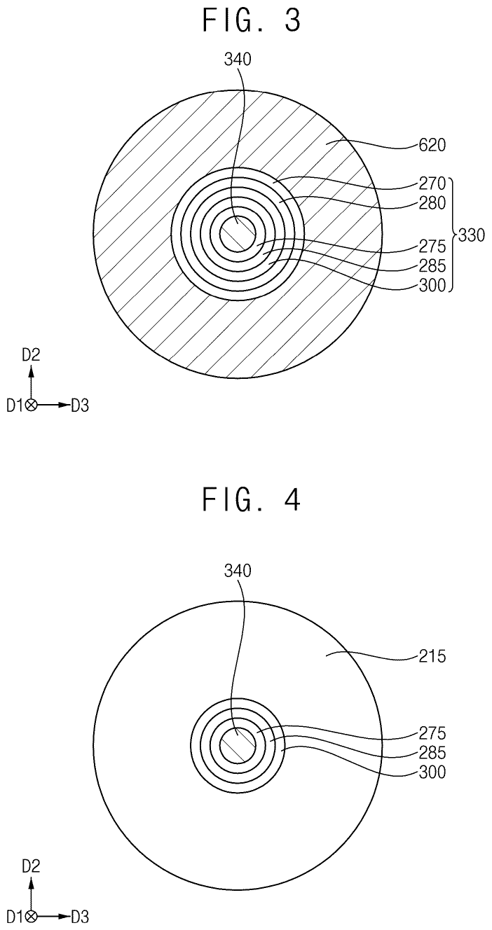

FIGS. 1 to 4 are vertical cross-sectional views and horizontal cross-sectional views illustrating a semiconductor device in accordance with example embodiments. Particularly, FIG. 1 is the vertical cross-sectional view, FIG. 2 is an enlarged cross-sectional view of region X of FIG. 1, FIG. 3 is a horizontal cross-sectional view taken along line A-A′ of FIG. 2, and FIG. 4 is a horizontal cross-sectional view taken along line B-B′ of FIG. 2.

Referring to FIGS. 1 to 4, the semiconductor device may include a transistor 120, first and second wiring structures 130 and 150, first and second insulating interlayers 140 and 160, first and second bonding layers 170 and 760, first and second contact plugs 710 and 750, first and second wirings 510 and 730, third to fifth insulating interlayers 250, 500 and 700, a sixth insulating interlayer, a seventh insulating interlayer 740, first and second gate electrodes 620 and 340, a first memory channel structure 330, first and second division patterns 490 and 630, a first insulation pattern 215 and a common source plate (CSP) 800 on a first substrate 100.

The first substrate 100 may include a semiconductor material, e.g., silicon, germanium, silicon-germanium, etc., or a III-V group compound semiconductor, e.g., GaP, GaAs, GaSb, etc. In example embodiments, the first substrate 100 may be a silicon-on-insulator (SOI) substrate or a germanium-on-insulator (GOI) substrate.

An active region 105 may be disposed on the first substrate 100, and a sidewall of the active region 105 may be covered by an isolation pattern 110 on the first substrate 100. The active region 105 may include substantially the same material as the first substrate 100, and the isolation pattern 110 may include an oxide, e.g., silicon oxide.

The transistor 120 may include a gate structure on the first substrate 100, and an impurity region at an upper portion of the active region 105 adjacent to the gate structure. The first wiring structure 130 may be electrically connected to the transistor 120, and may include, e.g., contact plugs, vias, wirings, etc. The first insulating interlayer 140 may be disposed on the first substrate 100, and may cover the transistor 120 and the first wiring structure 130.

The second wiring structure 150 may be disposed on the first wiring structure 130, and may be electrically connected to the first wiring structure 130. The second wiring structure 150 may include, e.g., contact plugs, vias, wirings, etc. The second insulating interlayer 160 may be disposed on the first insulating interlayer 140, and may cover the second wiring structure 150.

The first bonding layer 170 may be disposed on the second insulating interlayer 160, and may include a first bonding pad 175. The second bonding layer 760 may include a second bonding pad 765, and may be disposed on and bonded to the first bonding layer 170. The first and second bonding layers 170 and 760 bonded to each other may collectively form a bonding layer structure.

In example embodiments, a plurality of first bonding pads 175 may be spaced apart from each other in the horizontal direction, and a plurality of second bonding pads 765 may be spaced apart from each other in the horizontal direction. The first and second bonding pads 175 and 765 may contact each other to form a bonding pad structure.

Each of the first and second bonding layers 170 and 760 may include an insulating material, e.g., silicon carbonitride, silicon oxide, etc., and each of the first and second bonding pads 175 and 765 may include a metal, e.g., copper.

The seventh insulating interlayer 740 may be disposed on the second bonding layer 760, and the second contact plug 750 may extend through the seventh insulating interlayer 740.

The sixth insulating interlayer may be disposed on the seventh insulating interlayer 740, and the second wiring 730 may extend through the sixth insulating interlayer to contact an upper surface of the second contact plug 750. In example embodiments, the second wiring 730 may serve as a bit line of the semiconductor device. The second wiring 730 may extend in the third direction D3, and a plurality of second wirings 730 may be spaced apart from each other in the second direction D2.

The fifth insulating interlayer 700 may be disposed on the sixth insulating interlayer, and the fourth insulating interlayer 500 may be disposed on the fifth insulating interlayer 700.

The first contact plug 710 may extend through the fourth and fifth insulating interlayers 500 and 700 to contact an upper surface of the second wiring 730, and the first wiring 510 may extend through the fourth insulating interlayer 500. In example embodiments, the first wiring 510 may extend in the second direction D2, and a plurality of first wirings 510 may be spaced apart from each other in the third direction D3.

In an example embodiment, the first contact plug 710 may have a shape of a pillar extending in the first direction D1. Alternatively, the first contact plug 710 may have a shape of a circular ring.

The third insulating interlayer 250 may be disposed on the fourth insulating interlayer 500.

Each of the first to fifth insulating interlayers 140, 160, 250, 500 and 700, the sixth insulating interlayer and the seventh insulating interlayer 740 may include an oxide, e.g., silicon oxide, or a low-k dielectric material.

The first gate electrode 620 may extend in the second direction D2, and a plurality of first gate electrodes 620 may be disposed at a plurality of levels, respectively, that are spaced apart from each other in the first direction D1 to form a first gate electrode structure. In example embodiments, a plurality of first gate electrode structures may be spaced apart from each other in the third direction D3, and the second division pattern 630 may be disposed between ones of the first gate electrode structures neighboring in the third direction D3. The first insulation pattern 215 may be disposed between ones of the first gate electrodes 620 neighboring in the first direction D1.

The second division pattern 630 may extend in the second direction D2, and may extend through the first gate structure, the first insulation patterns 215 and the third and fourth insulating interlayers 250 and 500. The second division pattern 630 may also extend through a lower portion of the CSP 800.

The first gate electrodes 620 disposed in the first direction D1 may include, e.g., a ground select line (GSL), a string select line (SSL) and a word line. In an example embodiment, ones of the first gate electrodes 620 that are disposed at a lowermost level and a second level from below may serve as the SSLs, respectively, one of the first gate electrodes 620 that is disposed at an uppermost level may serve as the GSL, and ones of the that are disposed at other levels may serve as the word lines, respectively.

Some of the first gate electrodes 620, for example, ones of the first gate electrodes 620 that are disposed at a single level or a plurality of levels under the SSL and/or over the GSL may serve as gate induced drain leakage (GIDL) gate electrodes, which may perform body erase using GIDL phenomenon. Some of the first gate electrodes 620 serving as the word lines may be dummy word lines.

The first division pattern 490 may extend in the second direction D2, and may extend through some of the first gate electrodes 620, e.g., ones of the first gate electrodes 620 serving as the SSLs, the first insulation patterns 215 between the ones of the first gate electrodes 620, and the third and fourth insulating interlayers 250 and 500, and may separate the ones of the first gate electrodes 620 from each other in the third direction D3.

Each of the first and second division patterns 490 and 630 and the first insulation pattern 215 may include an oxide, e.g., silicon oxide.

The second gate electrode 340 may have a shape of a pillar extending in the first direction D1, and may extend through the first gate structure, the first insulation patterns 215 and the third insulating interlayer 250 to contact an upper surface of the first wiring 510. The second gate electrode 340 may also extend through the lower portion of the CSP 800. In example embodiments, a plurality of second gate electrodes 340 may be spaced apart from each other in each of the second and third directions D2 and D3. The second gate electrode 340 may serve as a back-gate with respect to the first gate electrode 620.

Each of the first and second gate electrodes 620 and 340 may include a metal, e.g., tungsten, aluminum, platinum, gold, titanium, etc., a metal nitride, e.g., titanium nitride, a metal carbide, e.g., titanium carbide, aluminum carbide, titanium aluminum carbide, etc., or carbon.

The first memory channel structure 330 may include a second ion reservoir pattern 275, a second electrolyte pattern 285 and a channel 300 that may be sequentially stacked on a sidewall and an upper surface of the second gate electrode 340 and have an upside-down cup shape, and a first electrolyte pattern 280 and a first ion reservoir pattern 270 that may be sequentially stacked on an outer sidewall of the channel 300 in the horizontal direction and have a shape of a circular ring.

In example embodiments, the first electrolyte pattern 280 and the first ion reservoir pattern 270 may be disposed at the same level, the first ion reservoir pattern 270 may contact a sidewall of a corresponding one of the first gate electrodes 620, and the first electrolyte pattern 280 may contact a portion of the outer sidewall of the channel 300. Thus, a plurality of first electrolyte patterns 280 may be disposed at a plurality of levels, respectively, that are spaced apart from each other in the first direction D1, and a plurality of first ion reservoir patterns 270 may be disposed at a plurality of levels, respectively, that are spaced apart from each other in the first direction D1.

In an example embodiment, the channel 300 may include an oxide semiconductor material, e.g., indium gallium zinc oxide (IGZO), indium gallium silicon oxide (IGSO), zinc tin oxide (ZTO), indium zinc oxide (IZO), indium oxide (InOₓ), zinc oxide (ZnOₓ), tin oxide (SnOₓ), titanium oxide (TiOₓ), etc.

Alternatively, the channel 300 may include a two-dimensional material, e.g., a transition metal chalcogenide including a transition metal and a chalcogen element. The channel 300 may include a material represented by a chemical formula such as MX or MX₂ (M: transition metal, X: chalcogen element).

The transition metal may include, e.g., molybdenum, tungsten, rhenium, technetium, niobium, tantalum, hafnium, zirconium, osmium, ruthenium, iridium, rhodium, platinum, palladium, yttrium, lanthanum, lutetium, scandium, titanium, vanadium, chrome, manganese, iron, cobalt, nickel, etc., and the chalcogen element may include, e.g., sulfur, selenium, tellurium, etc.

Thus, the channel 300 may include a two-dimensional material such as MoS, MoS₂, MoSe, MoSe₂, MoTe, MoTe₂, WS, WS₂, CuS, CuSe, CuTe, etc.

Alternatively, the channel 300 may include a metal oxide, e.g., WOₓ, MoOₓ, HfO₂, V₂O₅, CeO₂, ZrO₂, NbO₂, LiCoO₂, LiPON, praseodymium calcium manganese oxide (PCMO), etc.

Each of the first and second ion reservoir patterns 270 and 275 may include a hydrogen absorbing metal, e.g., palladium, platinum, titanium, etc., or a metal oxide, e.g., VO, WOₓ, MoO, TiO, LiCoO₂, CeO₂, TiO₂, etc.

Each of the first and second electrolyte patterns 280 and 285 may include, e.g., HfOₓ, LiPON, Li₃PO₄, CsHSO₄, KH₂PO₄, CsHSeO, LiPON, H₂SO₄, LaF₃, CuRbClI, LiAlTiPO, LiZrPO, Li₂S, Ta₂O₅, WO₃, Mg(BH₄)(NH₂), Mg(En)ₓ(BH₄)₂, LiCoO₂, LiLaZrO, P doped SiO₂, P₂O₅—SiO₂, MoO₃, SiO₂, LiClO₄, CeO₂, SrTiO₃, etc.

The CSP 800 may include, e.g., polysilicon doped with n-type impurities. Alternatively, the CSP 800 may have a multi-layered structure of a first layer including a metal silicide layer and a second layer including polysilicon doped with n-type impurities.

FIG. 1 shows that the semiconductor device has a cell over periphery (COP) structure in which memory cells, that is, the first and second gate electrodes 620 and 340 and the first memory channel structure 330 are disposed over a peripheral circuit pattern, that is, the transistor 120 and the first and second wiring structures 130 and 150 on the first substrate 100, and the memory cells and the peripheral circuit are electrically connected to each other through the first and second bonding pads 175 and 765 in the first and second bonding layers 170 and 760 between the memory cells and the peripheral circuit, however, the inventive concept is not limited thereto.

For example, the memory cells and the peripheral circuit may be electrically connected to each other without the first and second bonding pads 175 and 765, and the memory cells may be disposed under the peripheral circuit pattern so that the semiconductor device may have a periphery over cell (POC) structure.

The semiconductor device may be an electrochemical random access memory (ECRAM) device in which the first memory channel structure 330 may include the first ion reservoir pattern 270 and the first electrolyte pattern 280 between the first gate electrode 620 and the channel 300. The channel 300 may be electrically connected to the second wiring 730 serving as the bit line through the first contact plug 710.

In an ECRAM device including a memory channel structure having a channel, an ion reservoir pattern and an electrolyte pattern in accordance with a comparative embodiment, if, for example, a program voltage of about 20V is applied to the gate electrode included in a selected memory cell and for example, a pass voltage of about 9V is applied to the gate electrodes included in non-selected memory cells, a voltage difference of about 11V occurs between the selected memory cell and the non-selected memory cells neighboring to the selected memory cell.

However, the ECRAM device in example embodiments may further include the second gate electrode 340 that may extend in the first direction D1 adjacent to the channel 300 and be electrically connected to the first wiring 510, and the second gate electrode 340 may serve as a back-gate with respect to the first gate electrode 620. In example embodiments, during at least an operation (e.g., a program operation) of the semiconductor device (e.g., the ECRAM device), a portion of the first gate electrodes 620 (e.g., the first gate electrode 620 included in a selected memory cell) may receive a first voltage (e.g., a program voltage), another portion of the first gate electrodes 620 (e.g., the first gate electrodes 620 included in non-selected memory cells) may receive a second voltage (e.g., a pass voltage) lower (e.g., in magnitude) than the first voltage (e.g., the program voltage), and the second gate electrode 340 may receive a voltage that is substantially the same (e.g., in magnitude) as the second voltage (e.g., the pass voltage).

If, for example, a program voltage of about 20V is applied to the first gate electrode 620 included in a selected memory cell and for example, a pass voltage of about 9V is applied to the first gate electrodes 620 included in non-selected memory cells, for example, a voltage of about 9V may also be applied to the second gate electrode 340. A voltage of about 9V may be applied from the first gate electrode 620 to each of the non-selected memory cells in a first direction, and a voltage of about 9V may be applied from the second gate electrode 340 to each of the non-selected memory cells in a second direction that is opposite to the first direction, and the voltages may be cancelled out. Accordingly, a voltage difference of about 20V may occur between the selected memory cell and the non-selected memory cells neighboring the selected memory cell.

As a result, the voltage difference between the selected memory cell and the non-selected memory cells neighboring each other may increase, so that interference or disturbance between the memory cells may decrease.

The first memory channel structure 330 included in the ECRAM device in accordance with example embodiments may further include the second ion reservoir pattern 275 adjacent to the second gate electrode 340 in addition to the first ion reservoir pattern 270 adjacent to the first gate electrode 620.

If the number of the memory cells stacked in the first direction D1 of the ECRAM device increases, an amount of ions supplied to the channels 300 included in lower memory cells, which are located farther from the second wiring 730 serving as the bit line, may be insufficient. However, in example embodiments, the insufficient amount of ions may be replenished through ions stored in the second ion reservoir pattern 275.

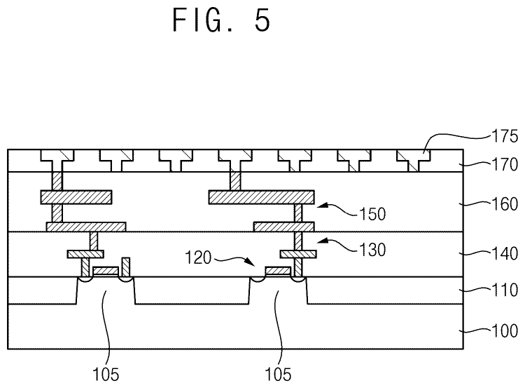

FIGS. 5 to 12 are cross-sectional views illustrating a method of manufacturing a semiconductor device in accordance with example embodiments.

Referring to FIG. 5, an upper portion of a first substrate 100 may be partially removed to form an active region 105, and an isolation pattern 110 may be formed on the first substrate 100 to cover a sidewall of the active region 105.

A transistor 120 and a first wiring structure 130 electrically connected to the transistor 120 may be formed on the active region 105, and a first insulating interlayer 140 may be formed on the active region 105 and the isolation pattern 110 to cover the transistor 120 and the first wiring structure 130.

The transistor 120 may include a gate structure disposed on the first substrate 100, and an impurity region at an upper portion of the active region 105 adjacent to the gate structure. The first wiring structure 130 may include, e.g., contact plugs, vias, wirings, etc.

A second wiring structure 150 may be formed on the first insulating interlayer 140 to be electrically connected to the first wiring structure 130, and a second insulating interlayer 160 may be formed on the first insulating interlayer 140 to cover the second wiring structure 150. The second wiring structure 150 may include, e.g., contact plugs, vias, wirings, etc.

A first bonding layer 170 including a first bonding pad 175 may be formed on the second insulating interlayer 160.

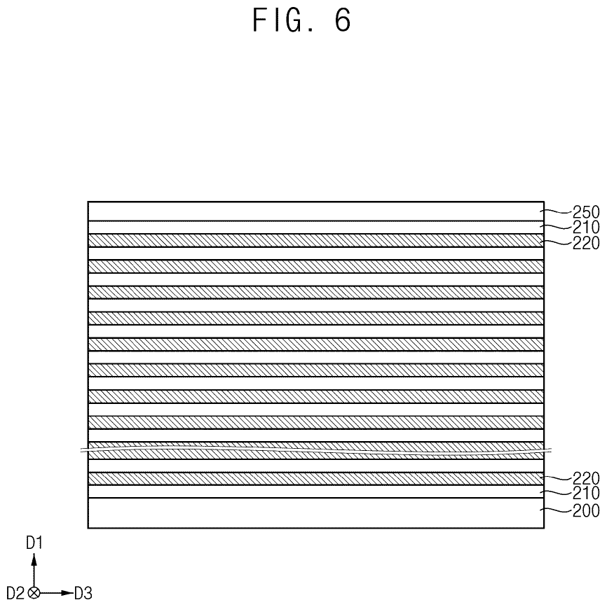

Referring to FIG. 6, first insulation layers 210 and sacrificial layers 220 may be alternately and repeatedly stacked on a second substrate 200, and thus a mold layer may be formed on the second substrate 200.

The first insulation layers 210 may include an oxide, e.g., silicon oxide, and the sacrificial layers 220 may include a material having a high etching selectivity with respect to the first insulation layers 210, e.g., an insulating nitride such as silicon nitride.

An etching process for patterning the mold layer using a photoresist pattern as an etching mask and a trimming process for reducing an area of the photoresist pattern may be performed alternately and repeatedly to form mold having a staircase shape and including a plurality of step layers each of which may include one first insulation layer 210 and one sacrificial layer 220 sequentially stacked.

A third insulating interlayer 250 may be formed on the second substrate 200 to cover the mold.

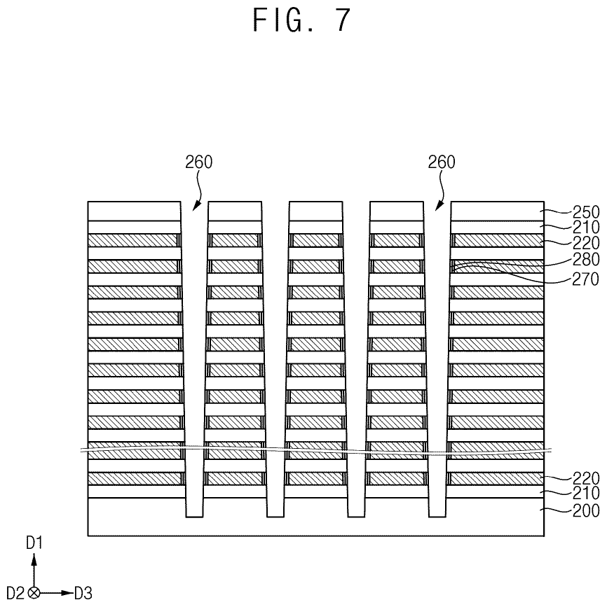

Referring to FIG. 7, a dry etching process may be performed to form holes 260 that may extend through the third insulating interlayer 250 and the mold to expose an upper surface of the second substrate 200.

In example embodiments, the dry etching process may be performed until each of the holes 260 exposes the upper surface of the second substrate 200, and further, until each of the holes 260 extends through an upper portion of the second substrate 200. In example embodiments, a plurality of holes 260 may be spaced apart from each other in each of the second and third directions D2 and D3.

Lateral portions of the sacrificial layers 220 exposed by the holes 260 may be removed by, e.g., a wet etching process to form first recesses.

A first ion reservoir layer may be formed on sidewalls of the holes 260, the upper surface of the second substrate 200 and an upper surface of the third insulating interlayer 250 to fill the first recesses, and, for example, a wet etching process may be performed on the first ion reservoir layer to form a first ion reservoir pattern 270 in a lateral portion of each of the first recesses.

A first electrolyte layer may be formed on the sidewalls of the holes 260, sidewalls of the first ion reservoir patterns 270, the upper surface of the second substrate 200 and the upper surface of the third insulating interlayer 250 to fill the first recesses, and, for example, a wet etching process may be performed on the first electrolyte layer to form a first electrolyte pattern 280 in a remaining portion of each of the first recesses.

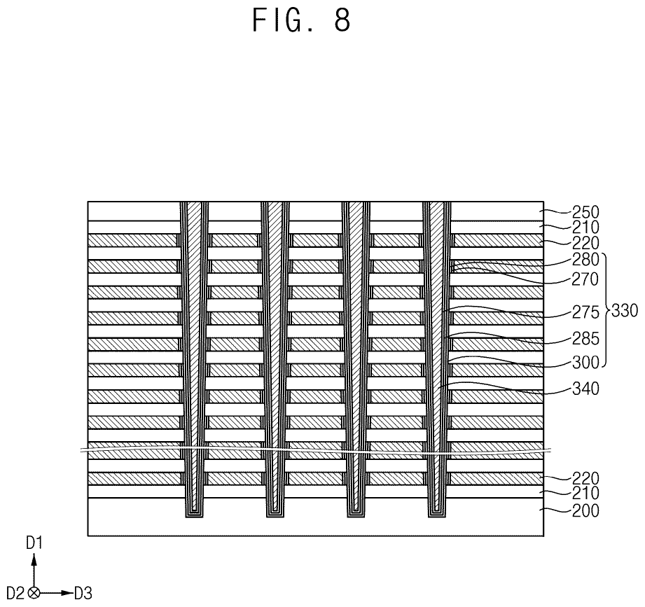

Referring to FIG. 8, a channel layer, a second electrolyte layer and a second ion reservoir layer may be sequentially stacked on inner walls of the holes 260 and the upper surface of the third insulating interlayer 250, a second gate electrode layer may be formed on the second ion reservoir layer to fill the holes 260, and a planarization process may be performed on the second gate electrode layer, the second ion reservoir layer, the second electrolyte layer and the channel layer until the upper surface of the third insulating interlayer 250 is exposed.

In example embodiments, the planarization process may include, e.g., a chemical mechanical polishing (CMP) process and/or an etch back process.

By the planarization process, a second gate electrode 340 having a shape of a pillar extending in the first direction D1, and a second ion reservoir pattern 275, a second electrolyte pattern 285 and a channel 300 sequentially stacked on a sidewall and a lower surface of the second gate electrode 340 may be formed. The second ion reservoir pattern 275, the second electrolyte pattern 285 and the channel 300, and the first electrolyte patterns 280 and the first ion reservoir patterns 270 on a sidewall of the channel 300 may collectively form a first memory channel structure 330.

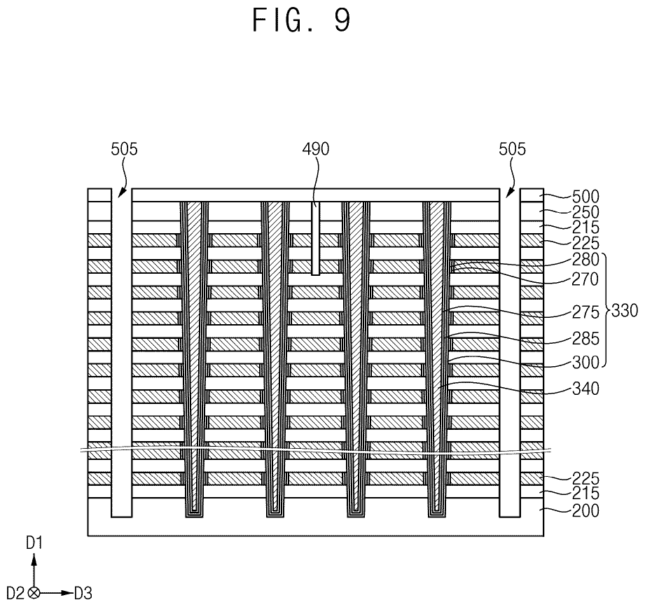

Referring to FIG. 9, the third insulating interlayer 250, ones of the first insulation layers 210 and ones of the sacrificial layers 220 may be partially removed to form a first opening extending in the second direction D2 through the third insulating interlayer 250, the ones of the first insulation layers 210 and the ones of the sacrificial layers 220, and a first division pattern 490 may be formed in the first opening.

A fourth insulating interlayer 500 may be formed on the third insulating interlayer 250, the first memory channel structure 330, the second gate electrode 340 and the first division pattern 490, and for example, a dry etching process may be performed to form second openings 505 extending through the third and fourth insulating interlayers 250 and 500 and the mold.

In example embodiments, the dry etching process may be performed until each of the second openings 505 may expose the upper surface of the second substrate 200, and further each of the second openings 505 may extend through the upper portion of the second substrate 200. As the second openings 505 are formed, the first insulation layers 210 and the sacrificial layers 220 may be exposed.

In example embodiments, each of the second openings 505 may extend in the second direction D2, and a plurality of second openings 505 may be spaced apart from each other in the third direction D3. As the second openings 505 are formed, the first insulation layer 210 may be divided into a plurality of first insulation patterns 215 each of which may extend in the second direction D2, and the sacrificial layer 220 may be divided into a plurality of sacrificial patterns 225 each of which may extend in the second direction D2.

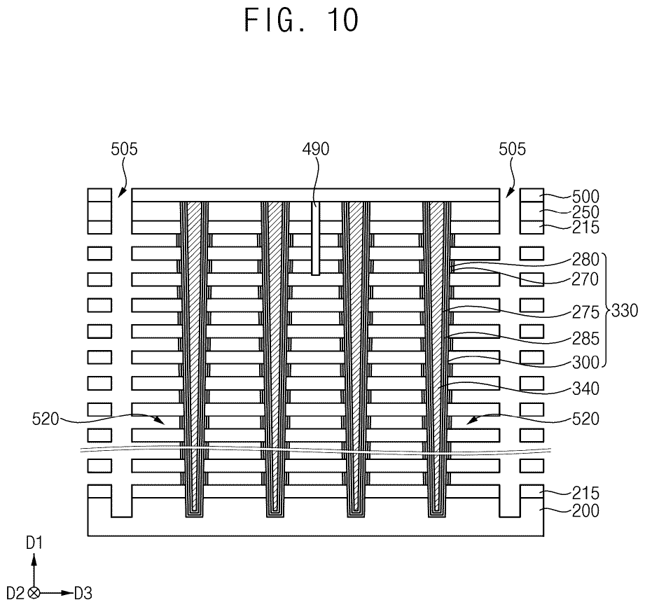

Referring to FIG. 10, for example, a wet etching process may be performed to remove the sacrificial patterns 225 to form gaps 520 exposing outer sidewalls of the first ion reservoir patterns 270 included in the first memory channel structures 330 and a sidewall of the first division pattern 490.

The wet etching process may be performed using an etching solution including, e.g., hydrofluoric acid (HF) and/or phosphoric acid (H₃PO₄).

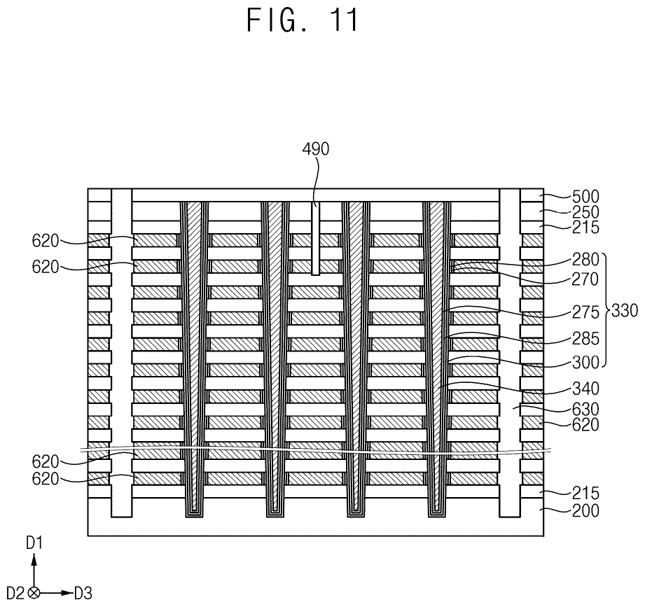

Referring to FIG. 11, a first gate electrode layer may be formed on the upper surface of the second substrate 200 and an upper surface of the fourth insulating interlayer 500 to fill the gaps 520, and for example, a wet etching process may be performed on the first gate electrode layer to form a first gate electrode 620 in each of the gaps 520.

In example embodiments, the first gate electrode 620 may extend in the second direction D2, and a plurality of first gate electrodes 620 may be stacked at a plurality of levels, respectively, spaced apart from each other in the first direction D1 to form a first gate electrode structure. A plurality of first gate electrode structures may be spaced apart from each other in the third direction D3 by the second openings 505.

A second division pattern 630 may be formed in the second opening 505.

Referring to FIG. 12, a first wiring 510 may be formed through the fourth insulating interlayer 500 to contact an upper surface of the second gate electrode 340.

In example embodiments, the first wiring 510 may extend in the second direction D2 to contact the upper surfaces of the second gate electrodes 340 disposed in the second direction D2, and a plurality of first wirings 510 may be spaced apart from each other in the third direction D3.

A fifth insulating interlayer 700 may be formed on the fourth insulating interlayer 500 and the first wiring 510, and a first contact plug 710 may be formed through the fourth and fifth insulating interlayers 500 and 700 to contact an upper surface of the channel 300. In an example embodiment, the first contact plug 710 may have a shape of a pillar contacting a portion of the upper surface of the channel 300. Alternatively, the first contact plug 710 may have a shape of a circular ring entirely contacting the upper surface of the channel 300.

A sixth insulating interlayer may be formed on the fifth insulating interlayer 700 and the first contact plug 710, and a second wiring 730 may be formed through the sixth insulating interlayer to contact an upper surface of the first contact plug 710. In example embodiments, the second wiring 730 may serve as a bit line of the semiconductor device. The second wiring 730 may extend in the third direction D3 to contact the upper surfaces of the first contact plugs 710 disposed in the third direction D3, and a plurality of second wirings 730 may be spaced apart from each other in the second direction D2.

A seventh insulating interlayer 740 may be formed on the sixth insulating interlayer and the second wiring 730, and a second contact plug 750 may be formed through the seventh insulating interlayer 740 to contact an upper surface of the second wiring 730.

A second bonding layer 760 including a second bonding pad 765 may be formed on the seventh insulating interlayer 740 and the second contact plug 750. The second bonding pad 765 may contact an upper surface of the second contact plug 750.

Referring to FIGS. 1 to 4 again, after flipping the second substrate 200, the first and second bonding layers 170 and 760 may be bonded to each other, and the first and second bonding pads 175 and 765 may contact each other.

The second substrate 200 may be removed by, e.g., a grinding process to expose an upper portion of the channel 300 included in the first memory channel structure 330 and an upper surface of an uppermost one of the first insulation patterns 215, a CSP layer may be formed on the exposed upper portion of the channel 300 and the uppermost one of first the insulation patterns 215, and the CSP layer may be patterned to form a CSP 800 to complete the fabrication of the semiconductor device.

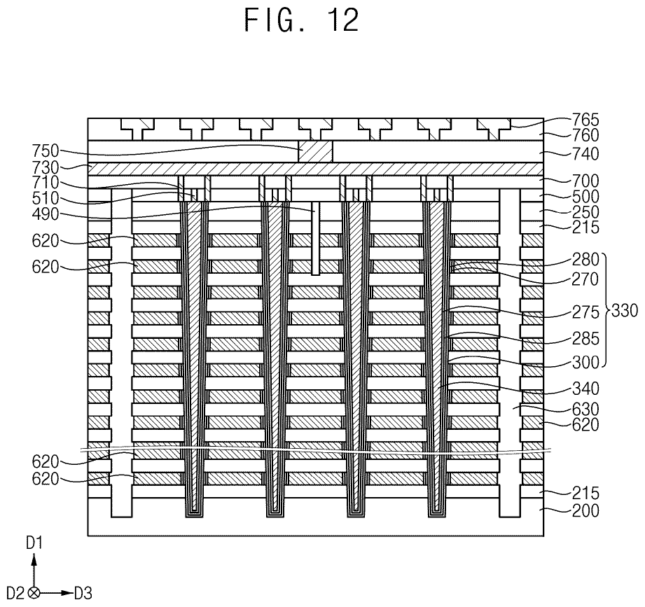

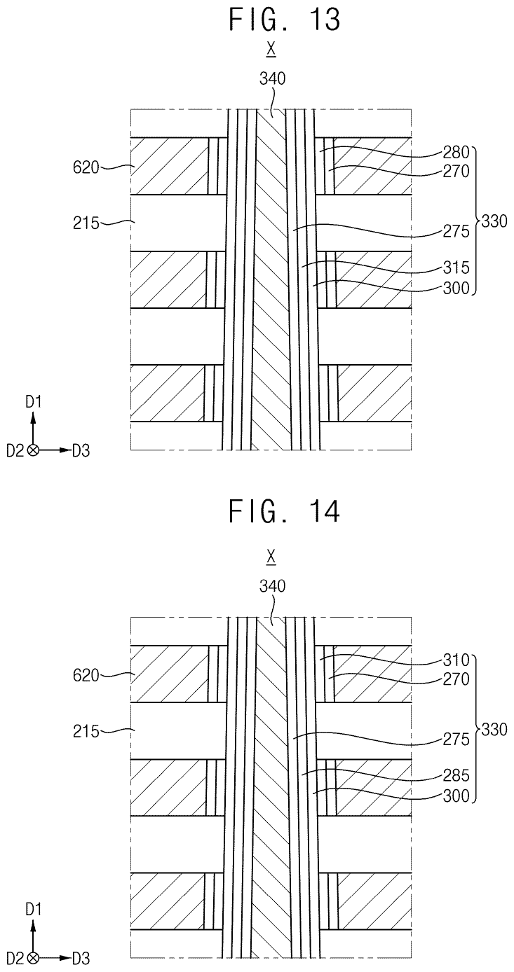

FIGS. 13 to 18 are enlarged cross-sectional views illustrating first memory channel structures included in semiconductor devices, respectively, in accordance with example embodiments, which may correspond to FIG. 2.

Referring to FIG. 13, the first memory channel structure 330 may include a second barrier pattern 315 instead of the second electrolyte pattern 285, between the channel 300 and the second ion reservoir pattern 275.

The second barrier pattern 315 may include a metal oxide, e.g., WO₃, TiO₂, HfO₂, V₂O₅, CeO₂, Al₂O₃, etc., a two-dimensional material, e.g., graphene, WS₂, or a metal nitride, e.g., WN, AlN, TaN, HfN, etc.

As the first memory channel structure 330 includes the second barrier pattern 315, for example, ions may be prevented from moving from the second ion reservoir pattern 275 to the channel 300 in non-selected memory cells.

Referring to FIG. 14, the first memory channel structure 330 may include a first barrier pattern 310 instead of the first electrolyte pattern 280, between the channel 300 and the first ion reservoir pattern 270.

The first barrier pattern 310 may include a metal oxide, e.g., WO₃, TiO₂, HfO₂, V₂O₅, CeO₂, Al₂O₃, etc., a two-dimensional material, e.g., graphene, WS₂, or a metal nitride, e.g., WN, AlN, TaN, HfN, etc.

As the first memory channel structure 330 includes the first barrier pattern 310, for example, ions may be prevented from moving from the first ion reservoir pattern 270 to the channel 300 in non-selected memory cells.

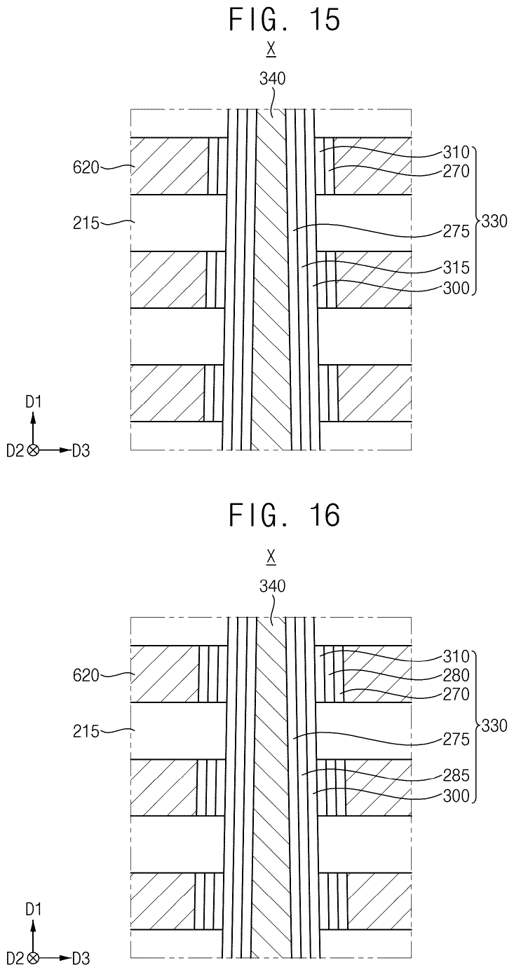

Referring to FIG. 15, the first memory channel structure 330 may include the first barrier pattern 310 instead of the first electrolyte pattern 280, between the channel 300 and the first ion reservoir pattern 270, and may include the second barrier pattern 315 instead of the second electrolyte pattern 285, between the channel 300 and the second ion reservoir pattern 275.

Referring to FIG. 16, the first memory channel structure 330 may further include the first barrier pattern 310 between the channel 300 and the first electrolyte pattern 280.

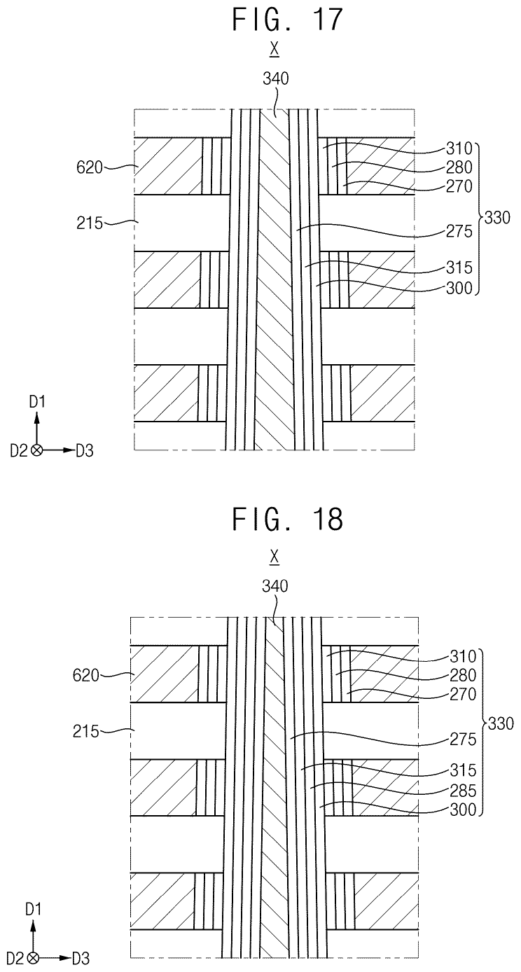

Referring to FIG. 17, the first memory channel structure 330 may further include the first barrier pattern 310 between the channel 300 and the first electrolyte pattern 280, and may further include the second barrier pattern 315 between the channel 300 and the second ion reservoir pattern 275.

Referring to FIG. 18, the first memory channel structure 330 may further include the first barrier pattern 310 between the channel 300 and the first electrolyte pattern 280, and further include the second barrier pattern 315 between the second ion reservoir pattern 275 and the second electrolyte pattern 285.

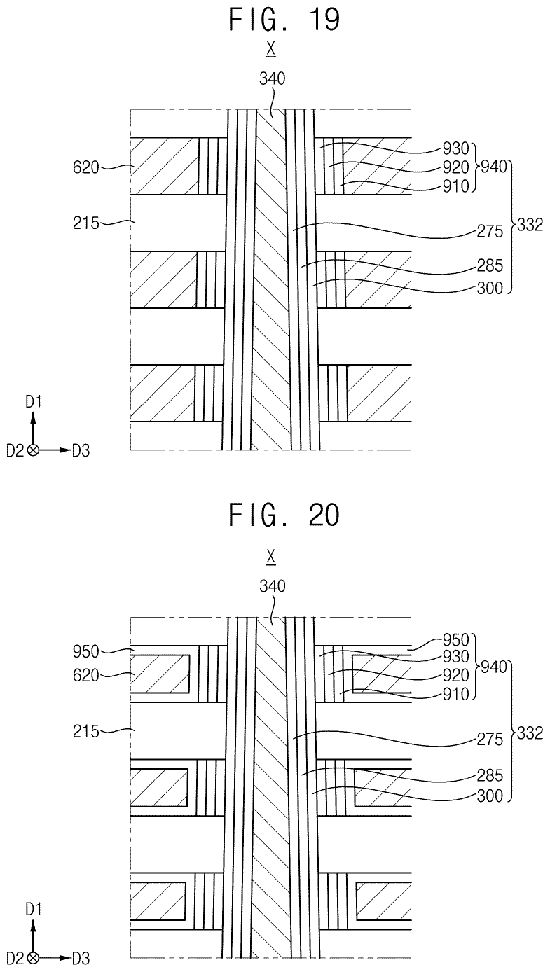

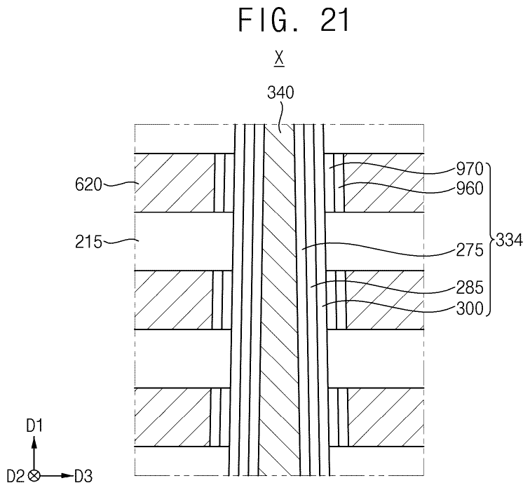

FIGS. 19 and 20 are enlarged cross-sectional views illustrating second memory channel structures included in semiconductor devices, respectively, in accordance with example embodiments, which may correspond to FIG. 2.

Each of the semiconductor devices may be, e.g., a flash memory device.

Referring to FIG. 19, the semiconductor device may include a second memory channel structure 332, which may include a charge storage structure 940 including a tunnel insulation pattern 930, a charge storage pattern 920 and a first blocking pattern 910 sequentially stacked in the horizontal direction between the channel 300 and the first gate electrode 620.

Each of the tunnel insulation pattern 930 and the first blocking pattern 910 may include an oxide, e.g., silicon oxide, and the charge storage pattern 920 may include an insulating nitride, e.g., silicon nitride.

Referring to FIG. 20, the second memory channel structure 332 may further include a second blocking pattern 950 between the first gate electrode 620 and the first blocking pattern 910, and the tunnel insulation pattern 930, the charge storage pattern 920 and the first and second blocking patterns 910 and 950 may collectively form the charge storage structure 940.

The second blocking pattern 950 may include a metal oxide, e.g., aluminum oxide.

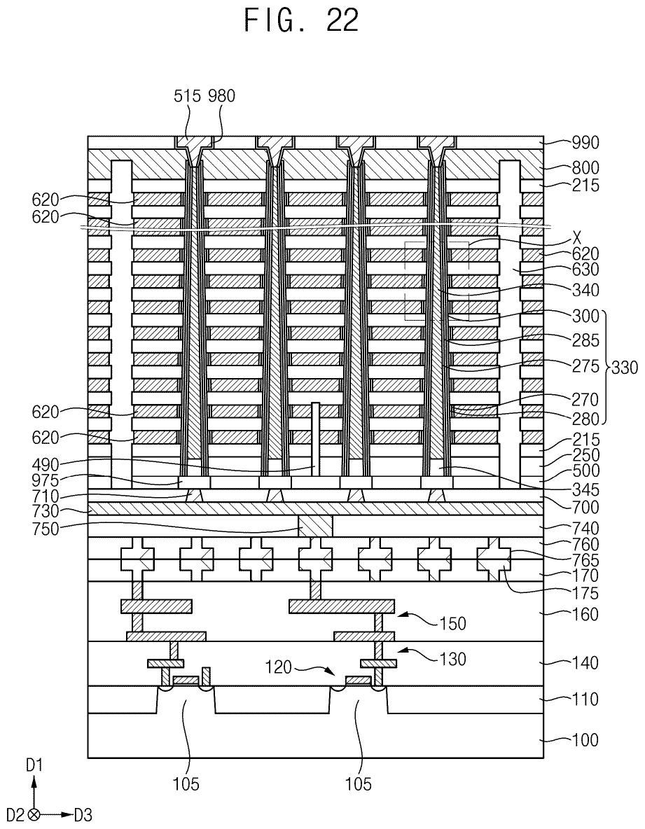

FIG. 21 is an enlarged cross-sectional view illustrating a third memory channel structure included in a semiconductor device in accordance with example embodiments, which may correspond to FIG. 2.

The semiconductor devices may be, e.g., a three-dimensional ferroelectric memory device.

Referring to FIG. 21, the semiconductor device may include a third memory channel structure 334, which may include an intermediate pattern 970 and a ferroelectric pattern 960 sequentially stacked in the horizontal direction between the channel 300 and the first gate electrode 620.

The ferroelectric pattern 960 may include, e.g., hafnium oxide doped with zirconium, silicon, aluminum, yttrium, gadolinium, lanthanum, scandium, strontium, etc.

The intermediate pattern 970 may include, e.g., silicon oxide or a metal oxide.

FIG. 22 is a cross-sectional view illustrating a semiconductor device in accordance with example embodiments, which may correspond to FIG. 1. This semiconductor device may be substantially the same as or similar to that of FIGS. 1 and 2, except for some elements, and thus repeated explanations are omitted herein.

Referring to FIG. 22, the first wiring 510 may not be disposed in the fourth insulating interlayer 500, and a pad 975 may extend through the fourth insulating interlayer 500 to contact a lower surface of the channel 300.

The first contact plug 710 may extend through the fifth insulating interlayer 700 to contact a lower surface of the pad 975. Thus, the second wiring 730 serving as the bit line may be electrically connected to the channel 300 through the first contact plug 710 and the pad 975.

A second insulation pattern 345 may be disposed under the second gate electrode 340, and may electrically insulate the second gate electrode 340 and the pad 975 from each other.

An eighth insulating interlayer 990 may be disposed on the CSP 800, and a third wiring 515 may extend through the eighth insulating interlayer 990 and the CSP 800 to contact the second gate electrode 340. In the semiconductor device of FIGS. 1 and 2, the first wiring 510 electrically connected to the second gate electrode 340 may be disposed under the second gate electrode 340, while in the semiconductor device of FIG. 21, the third wiring 515 electrically connected to the second gate electrode 340 may be disposed over the second gate electrode 340.

A third insulation pattern 980 may be disposed on a sidewall of the third wiring 515, and may electrically insulate the third wiring 515 and the CSP 800 from each other.

The pad 975 may include, e.g., polysilicon or doped polysilicon, the third wiring 515 may include a conductive material, e.g., a metal, a metal nitride, a metal silicide, etc., and each of the second and third insulation patterns 345 and 980 and the eighth insulating interlayer 990 may include, e.g., an oxide such as silicon oxide or an insulating nitride such as silicon nitride.

While example embodiments have been particularly shown and described, it will be understood by one of ordinary skill in the art that variations in form and detail may be made therein without departing from the spirit and scope of the claims.

What is claimed is:

1. A semiconductor device comprising:
first gate electrodes spaced apart from each other in a vertical direction perpendicular to an upper surface of a substrate;
a second gate electrode extending in the vertical direction through the first gate electrodes; and
a memory channel structure on a sidewall of the second gate electrode,
wherein the memory channel structure includes:
a second ion reservoir pattern disposed on the sidewall of the second gate electrode and extending in the vertical direction;
a second electrolyte pattern disposed on a sidewall of the second ion reservoir pattern and extending in the vertical direction;
a channel disposed on a sidewall of the second electrolyte pattern and extending in the vertical direction; and
first ion reservoir patterns between the channel and sidewalls of the first gate electrodes, respectively, the first ion reservoir patterns being spaced apart from each other in the vertical direction.

2. The semiconductor device of claim 1, further comprising first electrolyte patterns between the channel and the first ion reservoir patterns, respectively.

3. The semiconductor device of claim 2, further comprising first barrier patterns between the channel and the first electrolyte patterns, respectively.

4. The semiconductor device of claim 3, further comprising a second barrier pattern disposed between the second ion reservoir pattern and the second electrolyte pattern and extending in the vertical direction.

5. The semiconductor device of claim 1, further comprising first barrier patterns between the channel and the first ion reservoir patterns, respectively.

6. The semiconductor device of claim 5, wherein the second gate electrode is configured as a back-gate with respect to the first gate electrodes.

7. The semiconductor device of claim 6, wherein, during at least a program operation of the semiconductor device, a portion of the first gate electrodes receives a first voltage, another portion of the first gate electrodes receives a second voltage lower than the first voltage, and the second gate electrode receives a voltage that is the same as the second voltage.

8. The semiconductor device of claim 1, wherein each of the second ion reservoir pattern, the second electrolyte pattern and the channel has a shape of a cup.

9. The semiconductor device of claim 1, wherein each of the first ion reservoir patterns has a shape of a circular ring.

10. The semiconductor device of claim 1, further comprising:
a wiring electrically connected to the second gate electrode; and
a bit line electrically connected to the channel.

11. A semiconductor device comprising:
first gate electrodes spaced apart from each other in a vertical direction perpendicular to an upper surface of a substrate;
a second gate electrode extending in the vertical direction through the first gate electrodes; and
a memory channel structure on a sidewall of the second gate electrode,
wherein the memory channel structure includes:
a second ion reservoir pattern disposed on the sidewall of the second gate electrode and extending in the vertical direction;
a second barrier pattern disposed on a sidewall of the second ion reservoir pattern and extending in the vertical direction;
a channel disposed on a sidewall of the second barrier pattern and extending in the vertical direction; and
first ion reservoir patterns between the channel and sidewalls of the first gate electrodes, respectively, the first ion reservoir patterns being spaced apart from each other in the vertical direction.

12. The semiconductor device of claim 11, further comprising first electrolyte patterns between the channel and the first ion reservoir patterns, respectively.

13. The semiconductor device of claim 12, further comprising first barrier patterns between the channel and the first electrolyte patterns, respectively.

14. The semiconductor device of claim 11, further comprising first barrier patterns between the channel and the first ion reservoir patterns, respectively.

15. The semiconductor device of claim 14, wherein the second gate electrode is configured as a back-gate with respect to the first gate electrodes.

16. The semiconductor device of claim 15, wherein, during at least a program operation of the semiconductor device, a portion of the first gate electrodes receives a first voltage, another portion of the first gate electrodes receives a second voltage lower than the first voltage, and the second gate electrode receives a voltage that is the same as the second voltage.

17. A semiconductor device comprising:
a peripheral circuit pattern on a substrate;
a bit line on the peripheral circuit pattern;
first gate electrodes on the bit line, the first gate electrodes being spaced apart from each other in a vertical direction perpendicular to an upper surface of the substrate;
a second gate electrode extending in the vertical direction through the first gate electrodes;
a memory channel structure disposed on a sidewall of the second gate electrode and electrically connected to the bit line; and
a common source plate (CSP) disposed on and electrically connected to the memory channel structure,
wherein the memory channel structure includes:
a second ion reservoir pattern disposed on the sidewall of the second gate electrode and extending in the vertical direction;
a second electrolyte pattern or a second barrier pattern disposed on a sidewall of the second ion reservoir pattern and extending in the vertical direction;
a channel disposed on a sidewall of the second electrolyte pattern or the second barrier pattern and extending in the vertical direction; and
first ion reservoir patterns between the channel and sidewalls of the first gate electrodes, respectively, the first ion reservoir patterns being spaced apart from each other in the vertical direction.

18. The semiconductor device of claim 17, further comprising:
a wiring disposed on the bit line and electrically connected to the second gate electrode; and
a contact plug disposed between and contacting the bit line and the channel.

19. The semiconductor device of claim 17, further comprising a bonding layer structure between the peripheral circuit pattern and the bit line, the bonding layer structure including a bonding pad structure.

20. The semiconductor device of claim 17, further comprising first electrolyte patterns between the channel and the first ion reservoir patterns, respectively.
